(19) United States
(12) Patent Application Publication
(10) Pub. No.: US 2006/0292727 A1
(43) Pub. Date: Dec. 28, 2006

(54) Photomask plasma etching apparatus, etching method, and photomask forming method

(76) Inventors: Takeharu Motokawa, Zushi-shi (JP); Junichi Tonotani, Yokhama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/441,216

(22) Filed: May 26, 2006

(30) Foreign Application Priority Data
May 26, 2005 (JP) 2005-153947

(51) Int. Cl. H01L 21/00; H01L 21/306; H01L 21/302

(52) U.S. Cl. 438/30; 438/710; 156/345.51

(57) ABSTRACT

A photomask plasma etching apparatus includes an electrode to generate plasma, and an electrical capacity control unit configured to control an electrical capacity between the electrode and a mask substrate to be held on the electrode.

### CROSS-REFERENCE TO RELATED APPLICATIONS

This application is based upon and claims the benefit of priority from prior Japanese Patent Application No. 2005-153947, filed May 26, 2005, the entire contents of which are incorporated herein by reference.

### BACKGROUND OF THE INVENTION

1. Field of the Invention

The present invention relates to a photomask plasma etching apparatus, an etching method, and a photomask forming method which are used in the semiconductor field.

2. Description of the Related Art

There is a known method of making an etching rate (amount of etching) uniform by forming a coating film of the same quality as a portion to be etched on a photomask, and then performing plasma etching (Jpn. Pat. No. 3319568). In this method, the coating film of the same quality as the portion to be etched formed on the photomask needs to be removed afterward.

As another method of controlling the etching rate in photomask forming process, there is a method in which a focus ring (correction plate) is disposed on the exterior of a mask substrate. By disposing the focus ring, electric field fluctuations in a peripheral portion of the mask substrate can be corrected.

The influence of the aforementioned correction effect on an electric field distribution using the focus ring decreases from the peripheral portion to a central portion of the mask substrate. Therefore, the conventional etching method using the focus ring has a problem in the uniformity of an in-plane distribution of the etching rate of a mask substrate.

### BRIEF SUMMARY OF THE INVENTION

According to an aspect of the present invention, there is provided a photomask plasma etching apparatus comprising: an electrode to generate plasma; and an electrical capacity control unit configured to control an electrical capacity between the electrode and a mask substrate to be held on the electrode.

According to another aspect of the present invention, there is provided a photomask plasma etching apparatus comprising: an electrode configured to generate a plasma; a focus ring provided on the electrode and having an opening; and a substrate holding/electrical capacity control unit configured to hold a mask substrate on the electrode and control an electrical capacity between the electrode and the mask substrate, the substrate holding/electrical capacity control unit being removable from the focus ring.

According to an aspect of the present invention, there is provided a n etching method for etching a mask substrate by a photomask plasma etching apparatus comprising an electrode configured to generate a plasma, the mask substrate is held on the electrode, the method comprising: obtaining an electrical capacity corresponding to a desired etching rate distribution based on a relationship between an electrical capacity between the electrode and the mask substrate and an in-plane etching rate distribution of the mask substrate; and setting the electrical capacity between the electrode and the mask substrate to be the obtained electrical capacity.

According to an aspect of the present invention, there is provided a photomask forming method comprising: forming a resist pattern on a mask substrate including a transparent substrate and light shielding film formed on the transparent substrate; and etching the light shielding film using the resist pattern as a mask by a photomask plasma etching apparatus comprising an electrode configured to generate a plasma and the mask substrate being held on the electrode, the etching the light shielding film comprising obtaining an electrical capacity corresponding to a desired etching rate distribution based on a relationship between an electrical capacity between the electrode and the mask substrate and an in-plane etching rate distribution of the mask substrate; and setting the electrical capacity between the electrode and the mask substrate to be the obtained electrical capacity.

### BRIEF DESCRIPTION OF THE SEVERAL VIEWS OF THE DRAWING

FIG. 1 is a diagram schematically showing a conventional photomask plasma etching apparatus;

FIG. 2 is a diagram showing an equivalent circuit of the conventional photomask plasma etching apparatus;

FIG. 3 is a diagram showing an equivalent circuit of a photomask plasma etching apparatus according to an embodiment;

FIG. 4 is a cross-sectional view showing an electrode structure of the photomask plasma etching apparatus according to the embodiment;

FIG. 5 is a diagram showing a relationship between a distance from a center of a mask substrate and an etching rate;

FIG. 6 is a cross-sectional view showing an electrode structure of the photomask plasma etching apparatus according to the embodiment;

FIG. 7 is a cross-sectional view showing an electrode structure of a photomask plasma etching apparatus according to an embodiment;

FIG. 8 is a cross-sectional view showing an electrode structure of a photomask plasma etching apparatus according to an embodiment;

FIGS. 9A and 9B are cross-sectional views showing a plurality of photomask holding substrates according to the embodiment;

FIGS. 10A and 10B are cross-sectional views showing a plurality of other photomask holding substrates according to the embodiment;

FIG. 11 is a diagram schematically showing the photomask plasma etching apparatus according to the embodiment; and

FIG. 12 is a cross-sectional view showing an electrode structure of the photomask plasma etching apparatus according to the embodiment.

### DETAILED DESCRIPTION OF THE INVENTION

Embodiments of the present invention will be described below with reference to the drawings.

### First Embodiment

The present embodiment describes a photomask plasma etching apparatus and an etching method, in which by controlling an electrical capacity between a surface (top surface) of a lower electrode and a backside (bottom surface) of a mask substrate, the uniformity of an in-plane distribution of the etching rate of the mask substrate is achieved. The mask substrate includes a transparent substrate (e.g., a quartz substrate) and a light shielding film (e.g., a chromium film or a halftone film) formed on the transparent substrate.

Before describing the present embodiment, a conventional photomask plasma etching apparatus and a mask substrate etching method using the etching apparatus will be described.

FIG. 1 is a diagram schematically showing a conventional photomask plasma etching apparatus. The photomask plasma etching apparatus comprises a high-frequency power supply 1, a direct-current blocking capacitor 2, a lower electrode 3, and an upper electrode (counter electrode) 7. In FIG. 1, reference numerals 4 and 6 each denote a sheath, reference numeral 5 denotes plasma, and reference numeral 8 denotes a ground portion 8. The voltage at the ground portion 8 is 0 volt.

In order to prevent a backside of a mask substrate (not shown) from being damaged, a major part of the mask substrate is held in the vicinity of the lower electrode 3 so as not to be in contact with the lower electrode 3. Thus, there is always a gap between a surface (top surface) of the lower electrode 3 and the backside (bottom surface) of the mask substrate.

The pressure between the electrodes 3 and 7 is reduced by a vacuum pump to the optimum pressure range for plasma generation. By a process gas injected into a space between the electrodes 3 and 7 before etching begins, the pressure is adjusted.

In a state in which the pressure between the electrodes 3 and 7 is thus optimally adjusted, a high-frequency power is applied between the electrodes 3 and 7 by the high-frequency power supply 1, thereby generating a high-frequency electric field in the process gas. Electrons in the process gas are accelerated by the high-frequency electric field. Ionization occurs in the process gas by the accelerated electrons and, as a result, the plasma 5 is generated across the electrodes 3 and 7.

When the plasma 5 comes into contact with a metallic member or a dielectric member in the apparatus, a space-charge layer is formed at an interface between the plasma 5 and the metallic member or an interface between the plasma 5 and the dielectric member. The space-charge layer is normally called “sheath”. In FIG. 1, reference numerals 4 and 6 correspond to sheaths.

The direct-current blocking capacitor 2 is used to reduce damage to the lower electrode 3 and to stabilize plasma discharge. Accordingly, plasma generation is maintained and etching proceeds.

As can be seen from the above description, plasma is generated by a high-frequency power which is provided externally and thus it can be considered that the components of the photomask plasma etching apparatus and the plasma compose some sort of electric circuit.

Hence, to further simplify the photomask plasma etching apparatus represented in FIG. 1, an equivalent circuit of the apparatus is considered. The sheaths 4 and 6 each is a space-charge layer having a rectifying function. It is known that in a state in which the plasma is stably maintained, a region where a sheath is present (sheath region) has a lower electric potential than a region where plasma is present (plasma region). Furthermore, in the plasma region, the absorption of a high-frequency power is performed by Joule heating. That is, the sheath can be replaced by a component (equivalent circuit) in which a rectifier, an electric resistor, and a capacitor are coupled to one another in parallel. Further, the plasma can be replaced by an electric resistor.

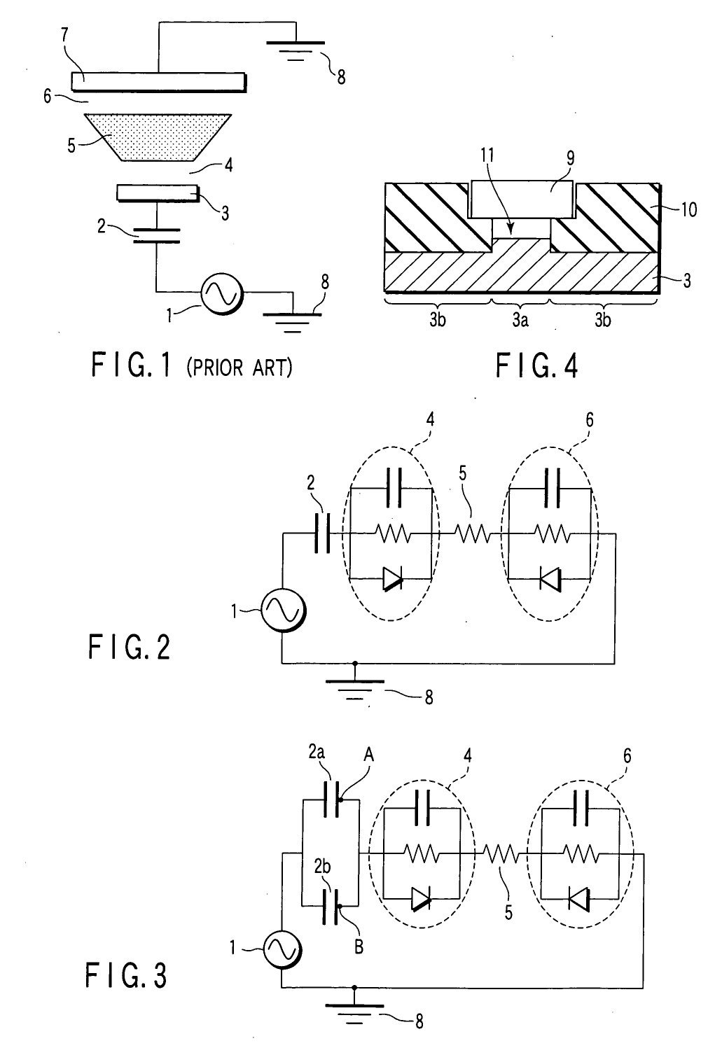

Taking into consideration the above, a conceptual diagram of the conventional photomask plasma etching apparatus shown in FIG. 1 can be replaced by an equivalent circuit shown in FIG. 2.

Next, a photomask plasma etching apparatus according to the present embodiment will be described. The photomask plasma etching apparatus has a configuration capable of controlling the electrical capacity between a surface (top surface) of the lower electrode 3 and a backside (bottom surface) of the mask substrate. An equivalent circuit of a photomask plasma etching apparatus in which the configuration is reflected is considered. Based on the equivalent circuit, the reason why an in-plane distribution of the etching rate of the mask substrate can be made uniform is described.

First, it is considered what equivalent circuit would replace a space between the surface of the lower electrode 3 and the backside of the mask substrate.

The surface of the lower electrode 3 is a conductor. Since the mask substrate is formed of quartz, the surface of the mask substrate is a dielectric. The surface of the mask substrate is in surface contact with the sheath 4. Therefore, the space between the surface of the lower electrode 3 and the backside of the mask substrate can be represented as a space sandwiched between an electrode having an electrical conduction property and a sheath. That is, the space between the surface of the lower electrode 3 and the backside of the mask substrate can be replaced by a capacitor in the equivalent circuit.

It can be said that in the equivalent circuit of the conventional apparatus of FIG. 2, the space between the surface of the lower electrode 3 and the backside of the mask substrate is represented as a part of the direct-current blocking capacitor 2. An action of purposefully controlling the electrical capacity between the surface of the lower electrode 3 and the backside of the mask substrate is equivalent to an action of replacing the conventional direct-current blocking capacitor 2 by a component in which a plurality of capacitors are coupled to one another in parallel.

FIG. 3 is a diagram showing an equivalent circuit of the photomask plasma etching apparatus according to the present embodiment which takes into consideration the above.

Bullet points A and B in FIG. 3 correspond to locations where the mask substrate is exposed to a sheath. The respective average values of the currents at bullet points A and B in FIG. 3 in the equivalent circuit are considered.

When capacitors represented by reference numerals 2a and 2b in FIG. 3 have different electrical capacities, the respective average values of the currents at bullet points A and B in FIG. 3 differ from each other. In view of this, the large-small (magnitude relation) relation of the electrical capacities of the capacitors represented by reference numerals 2a and 2b in FIG. 3 and the large-small relation (magnitude relation) of the current values of bullet points A and B in FIG. 3 are qualitatively considered.

When the electrical capacity of the capacitor represented by reference numeral 2a in FIG. 3 is larger than that of the capacitor represented by reference numeral 2b in FIG. 3, the average value of the current at point A is larger than that of the current at point B. This is because in the case where an electric resistor and a capacitor are connected in series in an alternating-current circuit, the impedance of the electrical capacity decreases as the electrical capacity increases and accordingly the average value of the current increases.

In this equivalent circuit too, such a relationship between the electrical capacity and the average value of the current exists. In the photomask plasma etching apparatus, increase/decrease of the current value in this equivalent circuit acts in line with increase/decrease of the etching rate. That is, by changing the electrical capacity between the surface of the lower electrode 3 and the backside of the mask substrate, the etching rate can be changed.

As described above, it can be seen that the etching rate can be controlled by the electrical capacity between the surface of the lower electrode 3 and the backside of the mask substrate. By controlling, in an arbitrary portion of the mask substrate, the electrical capacity between the surface of the lower electrode 3 and the backside of the mask substrate, the increase/decrease of the etching rate at the arbitrary portion can be controlled; as a result, the in-plane distribution of the etching rate can be controlled.

Namely, the present embodiment allows for control of the in-plane etching rate of the mask substrate by adding a function of controlling the electrical capacity of the space to a direct-current blocking function performed by the space between the surface of the lower electrode 3 and the backside of the mask substrate.

An example of such a photomask plasma etching apparatus that controls the in-plane distribution of the etching rate by controlling the electrical capacity between the surface of the lower electrode 3 and the backside of the mask substrate is provided below.

FIG. 4 is a diagram showing an electrode structure of a photomask plasma etching apparatus in which the electrical capacity between the surface of the lower electrode 3 and the backside of a mask substrate 9 is controlled by the distance of a gap 11 therebetween. Even if the distance of the gap 11 is the same, the electrical capacity may vary depending on the pattern of the photomask.

The lower electrode 3 is divided into a first lower electrode 3a and a second lower electrode 3b. The first lower electrode 3a is a projecting portion that projects toward the mask substrate 9. In the present embodiment, the electrical capacity is controlled by the distance between the first lower electrode 3a and the mask substrate 9. In the drawing, the second lower electrode 3b is a portion of the lower electrode 3 other than the first lower electrode 3a.

At the time of etching, the mask substrate 9 is placed on a focus ring 10. The focus ring 10 is made of a dielectric. The gap 11 is provided between the mask substrate 9 and the lower electrode 3a, and the gap 11 exists under a pattern region of the mask substrate 9. This is because if a backside of the pattern region of the mask substrate 9 comes into contact with the lower electrode 3a, a flaw or the like may occur on the backside. Such a flaw changes optical properties such as transmittance, causing a reduction in the yield of the mask substrate 9.

The size of the mask substrate 9 is representatively 15.24 cm (6 inches). The focus ring 10 has a planar shape of a circle, for example, and has a diameter of 30.48 to 38.1 cm (12 to 15 inches) and a thickness of 0.635 to 1.270 cm (¼ to ½ inch).

The distance of the gap 11 is defined by the relative position of the backside (plane Sa) of the mask substrate 9 and the surface (plane Sb) of the lower electrode 3a in FIG. 4. The distance of the gap 11 is on the order of 500 μm to several mm, for example.

By changing the height of the lower electrode 3a, the relative position of the plane Sa and the plane Sb in FIG. 4 is changed. In the present embodiment, the height of the lower electrode 3a is set to be 2 mm, 0 mm, and −2 mm with the position of a surface (plane Sc) of the lower electrode 3b as a reference position. The height of −2 mm indicates that the plane Sb is lower than the plane Sc by 2 mm.

The three types of lower electrodes are prepared and the following process is performed.

First, a halftone film of a molybdenum silicide compound is formed on a 6-inch square quartz substrate with a thickness of 0.25 inch, obtaining a mask substrate. A photoresist is then applied onto the halftone film by a spin-coating method to a thickness of 600 nm. The photoresist is then subjected to a baking process, after which a pattern is drawn on the photoresist. Thereafter, the photoresist is subjected to a development process, obtaining a resist pattern. Through such a process, the mask substrate having the quartz substrate, the halftone film, and the resist pattern is obtained as a sample.

Next, etching is performed using the resist pattern as a mask. Here, before the etching of the halftone film is completed, the etching is terminated.

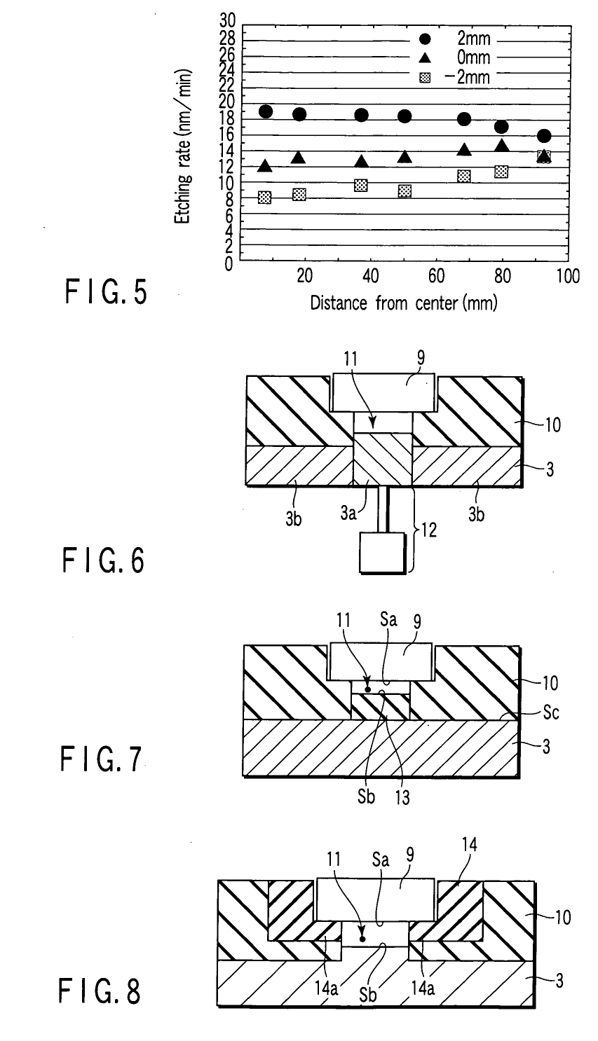

Thereafter, the amount of etching is determined by the difference in height between an etched region and a non-etched region of the halftone film, and the etching rate is calculated. The results are shown in FIG. 5. In FIG. 5, the horizontal axis represents the distance from the center of a sample (the center of a mask substrate) to a measurement point and the vertical axis represents the etching rate at each measurement point.

The results obtained from the etching using a lower electrode 3 with a lower electrode 3a having a height of 2 mm is shown by circle symbols in FIG. 5. Similarly, the results obtained from the etching using lower electrodes 3 whose respective lower electrodes 3a have heights of 0 mm and −2 mm are shown by triangle and square symbols in FIG. 5, respectively.

In FIG. 5, the trend of the circle symbol is descent toward right. Such a trend indicates that the etching rate is high at a central portion of the sample and relatively decreases toward a peripheral portion of the sample. That is, it indicates that etching rate control mainly in the central portion of the mask substrate can be performed.

On the other hand, the trends of the triangle and square symbols are ascent toward right. The square symbol significantly exhibits the trend. These trends indicate that the etching rate is low at a central portion of the sample and relatively increases toward a peripheral portion of the sample. That is, it indicates that etching rate control mainly in the peripheral portion of the mask substrate can be performed. Accordingly, it is found that in FIG. 5 the trend of the circle symbol differs from the trends of the triangle and square symbols.

As described above, it is verified that the in-plane distribution of the etching rate changes with a change in the distance of the gap 11 between the lower electrode 3 and the mask substrate 9. That is, it is verified that the in-plane distribution of the etching rate can be controlled by the change in the electrical capacity between the surface of the lower electrode 3a and the backside of the mask substrate 9. As a result, high-precision photomask etching is realized.

Moreover, by making the height of the central portion of the lower electrode 3a greater than that of the peripheral portion by the shape of the surface of the lower electrode 3a, for example, the electrical capacity between the lower electrode 3 and the central portion of the mask substrate 9 can be more effectively controlled. Therefore, stronger control of the etching rate can be performed on the central portion of the mask substrate 9. In contrast, by making the height of the central portion of the lower electrode 3a lower than that of the peripheral portion, the electrical capacity between the surface of the lower electrode 3 and the peripheral portion of the mask substrate 9 can be more effectively controlled. Therefore, stronger control of the etching rate can be performed on the peripheral portion of the mask substrate 9.

In the present embodiment, a lower electrode 3 having a height-variable lower electrode 3a may be used. Such a lower electrode 3 comprises, for example, as shown in FIG. 6, a lower electrode 3b having an opening, a lower electrode 3a inserted in the opening, and a drive mechanism 12 used to move the lower electrode 3a up and down.

An etching method of the present embodiment is as follows.

First, based on the relationship between the distance between the lower electrode 3 and the mask substrate 9 and the in-plane etching rate distribution of the mask substrate 9, such as the one shown in FIG. 5, a distance corresponding to a desired etching rate distribution is obtained.

The relationship between the distance and the etching rate distribution may be one created (prepared) in advance or one newly created for a photomask to be formed.

The influence of a correction effect on an electric field distribution using the focus ring 10 decreases from the peripheral portion to the central portion of the mask substrate 9. Therefore, the distance corresponding to the desired etching rate distribution is normally a distance corresponding to an etching rate distribution in which the etching rate is high at the central portion of the mask substrate 9 and relatively decreases toward the peripheral portion of the mask substrate 9.

Next, the distance between the lower electrode 3 and the mask substrate 9 is set so as to realize the obtained distance. Specifically, for example, the position in an up and down direction of the lower electrode 3a is adjusted by the drive mechanism 12 shown in FIG. 6 so as to realize the aforementioned distance.

Thereafter, a known process of forming a resist pattern on the mask substrate, generating plasma, and then etching the mask substrate using the resist pattern as a mask is performed.

Thus, according to the present embodiment, by controlling the distance between the lower electrode 3 and the mask substrate 9, the uniformity of the in-plane distribution of the etching rate of the mask substrate 9 is achieved.

### Second Embodiment

FIG. 7 is a diagram showing an electrode structure of a photomask plasma etching apparatus according to a second embodiment. Note that in the following drawing the same reference numerals as those described in the foregoing drawings denote the same reference numerals or corresponding portions and thus a detailed description thereof is omitted.

A dielectric member 13 is provided on a lower electrode 3. A gap 11 exists between the dielectric member 13 and a mask substrate 9. In the present embodiment, the electrical capacity between a surface of the lower electrode 3 and a backside of the mask substrate 9 is controlled by the dielectric member 13. Even if the dielectric member 13 is the same, the electrical capacity may vary depending on the pattern of the photomask.

The permittivity between the surface of the lower electrode 3 and the backside of the mask substrate 9 is defined by a combination of the permittivity of the dielectric member 13 and the permittivity of the gap 11. That is, when the permittivity of the dielectric member 13 is changed, the permittivity between the surface of the lower electrode 3 and the backside of the mask substrate 9 is changed. This change in permittivity consequently indicates a change in the electrical capacity between the surface of the lower electrode 3 and the backside of the mask substrate 9.

An influence on the etching rate caused by the aforementioned change in electrical capacity is examined. Using a member made of quartz as the dielectric member 13, the permittivity of a portion which is conventionally a gap is increased. In addition, the etching rate is examined for the case of a conventional electrode structure in which the dielectric member 13 does not exist (the case in which the entire space between the surface of the lower electrode 3 and the backside of the mask substrate 9 is a vacuum).

The same sample as that used in the first embodiment was prepared. Note that the sample of the present embodiment is different from that of the first embodiment in that a chromium film (light shielding film) is formed on a mask substrate and the size of the sample is 3-inch square. In addition, the etching of the present embodiment is different from that of the first embodiment in that the object to be etched is a chromium film.

In the case of the conventional electrode structure (a vacuum), the etching rate was 35.4 nm/min. On the other hand, in the case of the electrode structure (quartz+a vacuum) of the present embodiment, the etching rate was 38.0 nm/min. That is, it was verified that by employing the electrode structure of the present embodiment, the etching rate can be increased.

Taking into consideration the fact that quartz has a higher permittivity than a vacuum in a high-frequency electric field, the provision of the dielectric member 13 on the lower electrode 3 as shown in FIG. 7 is equivalent to an increase in the electrical capacity between the surface of the lower electrode 3 and the backside of the mask substrate 9. That is, it was verified that the etching rate can be changed by a change in the electrical capacity between the surface of the lower electrode 3 and the backside of the mask substrate 9. Furthermore, by causing such a change in the electrical capacity between the surface of the lower electrode 3 and the backside of the mask substrate 9 to occur in an arbitrary portion, it is possible to change the in-plane distribution of the etching rate.

An etching method of the present embodiment is as follows.

First, based on the relationship between the permittivity between the lower electrode 3 and the mask substrate 9 and the in-plane etching rate distribution of the mask substrate 9, a permittivity corresponding to a desired etching rate distribution is obtained.

The relationship between the permittivity and the etching rate distribution may be one created (prepared) in advance or one newly created for a photomask to be formed.

The influence of a correction effect on an electric field distribution using the focus ring 10 decreases from the peripheral portion to the central portion of the mask substrate 9. Therefore, the permittivity corresponding to the desired etching rate distribution is normally a permittivity corresponding to an etching rate distribution in which the etching rate is high at the central portion of the mask substrate 9 and relatively decreases toward the peripheral portion thereof.

Next, the permittivity between the lower electrode 3 and the mask substrate 9 is set so as to realize the obtained permittivity. Specifically, for example, the dielectric member 13 is used with which the obtained permittivity is realized by a permittivity obtained by combining the permittivity of the dielectric member 13 and the permittivity of the gap 11 (vacuum).

Thereafter, a known process of forming a resist pattern on the mask substrate, generating plasma, and then etching the mask substrate using the resist pattern as a mask is performed.

Thus, according to the present embodiment, by controlling the permittivity between the lower electrode 3 and the mask substrate 9, the uniformity of the in-plane distribution of the etching rate of the mask substrate 9 is achieved.

### Third Embodiment

FIG. 8 is a diagram showing an electrode structure of a photomask plasma etching apparatus according to a third embodiment.

In the present embodiment, by changing the structure (thickness or permittivity) of a bottom portion (a portion that holds a mask substrate 9 from the bottom) 14a of a photomask holding substrate 14, the electrical capacity between a surface of a lower electrode 3 and a backside of the mask substrate 9 is controlled. The planar shape of the photomask holding substrate 14 is representatively a circle.

Although a focus ring 10 is integrally formed with the lower electrode 3, the photomask holding substrate 14 can be removed from the focus ring 10. Thus, various photomask holding substrates 14 having different structures can be placed on the focus ring 10. Placement of the photomask holding substrate 14 on the focus ring 10 and removal of the photomask holding substrate 14 from the focus ring 10 are performed by a mechanism (e.g., a robot) which is not shown.

At the time of etching, the mask substrate 9 and the photomask holding substrate 14 are carried into the etching apparatus. Here, the mask substrate 9 is carried into the etching apparatus with the mask substrate 9 being held by the photomask holding substrate 14. Etching is performed with the photomask holding substrate 14 being placed on the focus ring 10 and the mask substrate 9 being held by the photomask holding substrate 14. After the etching process is completed, the mask substrate 9 and the photomask holding substrate 14 are carried out of the etching apparatus.

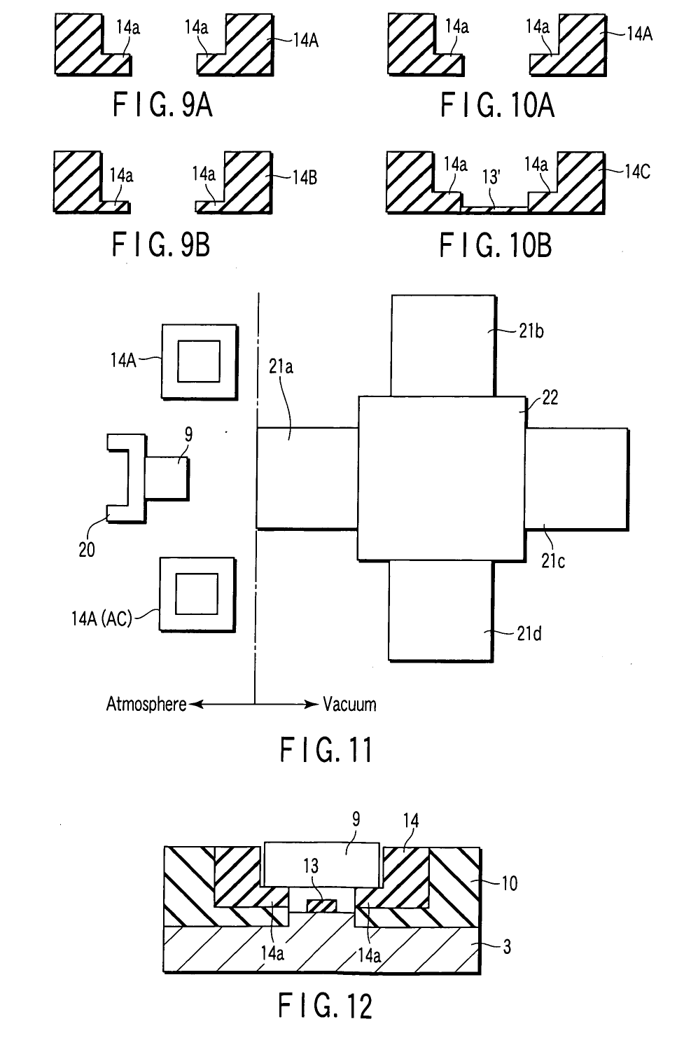

FIGS. 9A and 9B are diagrams respectively showing two types of photomask holding substrates 14A and 14B whose respective bottom portions 14a have different thicknesses d. Here, the photomask holding substrate 14A is a reference substrate. The thickness d of the photomask holding substrate 14B is thinner than the thickness d of the reference photomask holding substrate 14A.

A mask substrate 9 held by the photomask holding substrate 14A is different from a mask substrate 9 held by the photomask holding substrate 14B in distance between a backside (plane Sa) of the mask substrate 9 and a surface (plane Sb) of a lower electrode 3a. That is, the distance between the plane Sa and the plane Sb is longer in the mask substrate 9 held by the photomask holding substrate 14A than in the mask substrate 9 held by the photomask holding substrate 14B.

Hence, the distance (electrical capacity) between the surface of the lower electrode 3a and the backside of the mask substrate 9 can be changed by the thickness of the bottom portion 14a of the photomask holding substrate 14. Accordingly, the in-plane distribution of the etching rate can be changed, and thus, the uniformity of the in-plane distribution of the etching rate is achieved by the same principle as that described in the first embodiment.

Here, the two photomask holding substrates 14 whose respective bottom portions 14a have different thicknesses are prepared, three or more photomask holding substrates 14 whose respective bottom portions 14a have different thicknesses may be prepared.

FIGS. 10A and 10B are diagrams respectively showing two types of photomask holding substrates 14A and 14C whose respective bottom portions 14a have different structures. Specifically, the bottom portion 14a of the photomask holding substrate 14A has an opening, and the bottom portion 14a of the photomask holding substrate 14C has a dielectric member 13′ provided at a portion corresponding to the opening.

A mask substrate 9 held by the photomask holding substrate 14A is different from a mask substrate 9 held by the photomask holding substrate 14C in permittivity between a backside (plane Sa) of the mask substrate 9 and a surface (plane Sb) of a lower electrode 3a.

Hence, the electrical capacity between the surface of the lower electrode 3a and the backside of the mask substrate 9 can be changed by the type (permittivity) of the dielectric member 13′ of the photomask holding substrate 14C. Accordingly, the in-plane distribution of the etching rate can be changed, and thus, the uniformity of the in-plane distribution of the etching rate is achieved by the same principle as that described in the second embodiment.

Here, the two photomask holding substrates 14A and 14C whose respective bottom portions 14a have different permittivities are prepared, three or more photomask holding substrates 14 whose respective bottom portions 14a have different permittivities may be prepared.

Further, a plurality of photomask holding substrates 14 may be prepared which include at least one photomask holding substrate 14 having an opening in a bottom portion 14a (the thickness of the bottom portion 14a is different from one another) and at least one photomask holding substrate 14 having a dielectric member 13′ at a bottom portion 14a (the permittivity of the bottom portion 14a is different from one another).

An etching method in the case of using photomask holding substrates of types shown in FIGS. 9A and 9B is as follows.

First, based on the relationship between the distance between the lower electrode 3 and the mask substrate 9 and the in-plane etching rate distribution of the mask substrate 9, such as the one shown in FIG. 5, a distance corresponding to a desired etching rate distribution is obtained.

The relationship between the thickness and the etching rate distribution may be one created (prepared) in advance or one newly created for a photomask to be formed.

The influence of a correction effect on an electric field distribution using the focus ring 10 decreases from the peripheral portion to the central portion of the mask substrate 9. Therefore, when considering only the influence of the focus ring 10, the distance corresponding to the desired etching rate distribution is normally a distance corresponding to an etching rate distribution in which the etching rate is high at the central portion of the mask substrate 9 and relatively decreases toward the peripheral portion thereof.

Note, however, that the etching rate distribution actually has two cases, the case in which the central portion has a high etching rate and the case in which the central portion has a low etching rate. The reason for this is because the etching rate distribution is not determined only by the focus ring 10. For example, the etching rate distribution also changes by the selection of a plasma source.

However, in either of the cases in which the central portion has a high etching rate and in which the central portion has a low etching rate, by selecting a distance corresponding to the desired etching rate distribution, i.e., by selecting, for the case in which the central portion has a high etching rate, a distance that makes the etching rate at the central portion low and selecting, for the case in which the central portion has a low etching rate, a distance that makes the etching rate at the central portion high, the uniformity of the in-plane etching rate can be achieved. Thus, the method of the present embodiment is effective for either of the cases in which the central portion has a high etching rate and in which the central portion has a low etching rate.

Next, the distance between the lower electrode 3 and the mask substrate 9 is set so as to realize the obtained distance or a distance close thereto. Specifically, for example, from a plurality of photomask holding substrates 14 whose respective bottom portions 14a have different thicknesses which are prepared in advance, a photomask holding substrate 14 is selected with which the distance between the lower electrode 3 and the mask substrate 9 realizes the obtained distance or a distance close thereto. Then, the selected photomask holding substrate 14 is placed on the focus ring 10. The selected photomask holding substrate 14 is placed on the focus ring 10 with the photomask holding substrate 14 holding the mask substrate 9.

Thereafter, a known process of generating plasma and etching the mask substrate is performed.

An etching method used for the case of using photomask holding substrates of types shown in FIGS. 10A and 10B is as follows.

First, based on the relationship between the permittivity between the lower electrode 3 and the mask substrate 9 and the in-plane etching rate distribution of the mask substrate 9, a permittivity corresponding to a desired etching rate distribution is obtained.

The relationship between the permittivity and the etching rate distribution may be one created (prepared) in advance or one newly created for a photomask to be formed.

The influence of a correction effect on an electric field distribution using the focus ring 10 decreases from the peripheral portion to the central portion of the mask substrate 9. Therefore, when considering only the influence of the focus ring 10, the permittivity corresponding to the desired etching rate distribution is normally a permittivity corresponding to an etching rate distribution in which the etching rate is high at the central portion of the mask substrate 9 and relatively decreases toward the peripheral portion of the mask substrate 9.

Note, however, that as described above the method of the present embodiment is effective for either of the cases in which the central portion has a high etching rate and in which the central portion has a low etching rate.

Next, the permittivity between the lower electrode 3 and the mask substrate 9 is set so as to realize the obtained permittivity or a permittivity close thereto. Specifically, from a plurality of photomask holding substrates 14 whose respective bottom portions 14a have different permittivities which are prepared in advance, a photomask holding substrate 14 is selected with which the permittivity between the lower electrode 3 and the mask substrate 9 realizes the obtained permittivity or a permittivity close thereto. Then, the selected photomask holding substrate 14 is placed on the focus ring 10. The selected photomask holding substrate 14 is placed on the focus ring 10 with the photomask holding substrate 14 holding the mask substrate 9.

Thereafter, a known process of forming a resist pattern on the mask substrate, generating plasma, and then etching the mask substrate using the resist pattern as a mask is performed.

Thus, according to the present embodiment, by controlling the distance or permittivity between the lower electrode 3 and the mask substrate 9 by the photomask holding substrate 14, the uniformity of the in-plane distribution of the etching rate of the mask substrate 9 is achieved.

The etching method of the present embodiment is easily performed using, for example, a photomask plasma etching apparatus having a load lock mechanism shown in FIG. 11. In FIG. 11, reference numeral 20 denotes a robot, reference numerals 21a to 21d each denote a process module, and reference numeral 22 denotes a transfer chamber. At least one of the process modules 21a to 21d is a process module (etching module) used to perform etching by a plasma etching apparatus comprising the electrode structure of the present embodiment.

When the photomask holding substrates 14A and 14B of FIGS. 9A and 9B are used, the mask substrate 9 is placed on the photomask holding substrate 14A or 14B by the robot 20 and held thereby. When the photomask holding substrates 14A and 14C of FIGS. 10A and 10B are used, the mask substrate 9 is placed on the photomask holding substrate 14A or 14C by the robot 20 and held thereby. The photomask holding substrate 14 (14A, 14B, or 14C) and the mask substrate 9 are introduced into the etching module by the robot 20 and etching of the present embodiment is performed in the etching module.

Instead of providing the dielectric member 13′ at a bottom portion of the photomask holding substrate 14, a dielectric member 13 may be provided on a lower electrode 3, as shown in FIG. 12.

Note that the present invention is not limited to the aforementioned embodiments. For example, the present invention can be applied to a photomask plasma etching apparatus other than the photomask plasma etching apparatuses described in the aforementioned embodiments, as long as the apparatus has an electrode to which an RF power (high-frequency power) is applied. For example, the present invention can be applied to a photomask plasma etching apparatus having a plasma source, such as an ICP, to increase plasma density.

Note also that although the aforementioned embodiments describe the case in which there are two electrodes (a lower electrode and an upper electrode), the present invention can be applied to the case in which there is a single electrode. For example, in the case of a photomask plasma etching apparatus using an ICP as a plasma source, a single electrode will suffice.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A photomask plasma etching apparatus comprising:
an electrode to generate a plasma; and
an electrical capacity control unit configured to control an electrical capacity between the electrode and a mask substrate to be held on the electrode.

2. The photomask plasma etching apparatus according to claim 1, wherein the electrical capacity control unit includes a distance control unit to control a distance between the electrode and the mask substrate.

3. The photomask plasma etching apparatus according to claim 2, further comprising a focus ring provided on the electrode and having an opening.

4. The photomask plasma etching apparatus according to claim 3, further comprising a counter electrode facing the electrode.

5. A photomask plasma etching apparatus comprising:
an electrode configured to generate plasma;
a focus ring provided on the electrode and having an opening; and
a substrate holding/electrical capacity control unit configured to hold a mask substrate on the electrode and control an electrical capacity between the electrode and the mask substrate, the substrate holding/electrical capacity control unit being removable from the focus ring.

6. The photomask plasma etching apparatus according to claim 5, wherein
the substrate holding/electrical capacity control unit includes a plurality of first substrate holding/electrical capacity control units on which the mask substrate is placed and whose respective bottom portions have different thicknesses; a plurality of second substrate holding/electrical capacity control units whose respective portions facing a bottom surface of the mask substrate have different permittivities; or a plurality of the first and second substrate holding/electrical capacity control units, and
the photomask plasma etching apparatus further comprises a placement unit configured to place a desired substrate holding/electrical capacity control unit selected from the plurality of substrate holding/electrical capacity control units on the focus ring.

7. The photomask plasma etching apparatus according to claim 6, further comprising a counter electrode facing the electrode.

8. An etching method for etching a mask substrate by a photomask plasma etching apparatus comprising an electrode configured to generate plasma, the mask substrate is held on the electrode, the method comprising:
obtaining an electrical capacity corresponding to a desired etching rate distribution based on a relationship between an electrical capacity between the electrode and the mask substrate and an in-plane etching rate distribution of the mask substrate; and
setting the electrical capacity between the electrode and the mask substrate to be the obtained electrical capacity.

9. The etching method according to claim 8, further comprising:
preparing in advance a plurality of first substrate holding/electrical capacity control units on which the mask substrate is placed and whose respective bottom portions have different thicknesses; a plurality of second substrate holding/electrical capacity control units whose respective portions facing a bottom surface of the mask substrate have different permittivities; or a plurality of the first and second substrate holding/electrical capacity control units,
and wherein the setting of the electrical capacity between the electrode and the mask substrate to be the obtained electrical capacity includes placing a substrate holding/electrical capacity control unit which corresponds to the obtained electrical capacity and is selected from the plurality of substrate holding/electrical capacity control units on a focus ring; and placing the mask substrate on the selected substrate holding/electrical capacity control unit.

10. A photomask forming method comprising:
forming a resist pattern on a mask substrate including a transparent substrate and light shielding film formed on the transparent substrate; and
etching the light shielding film using the resist pattern as a mask by a photomask plasma etching apparatus comprising an electrode configured to generate a plasma and the mask substrate being held on the electrode, the etching the light shielding film comprising obtaining an electrical capacity corresponding to a desired etching rate distribution based on a relationship between an electrical capacity between the electrode and the mask substrate and an in-plane etching rate distribution of the mask substrate; and setting the electrical capacity between the electrode and the mask substrate to be the obtained electrical capacity.

11. The photomask forming method according to claim 10, further comprising:
preparing in advance a plurality of first substrate holding/electrical capacity control units on which the mask substrate is placed and whose respective bottom portions have different thicknesses; a plurality of second substrate holding/electrical capacity control units whose respective portions facing a bottom surface of the mask substrate have different permittivities; or a plurality of the first and second substrate holding/electrical capacity control units,
and wherein the setting of the electrical capacity between the electrode and the mask substrate to be the obtained electrical capacity includes placing a substrate holding/electrical capacity control unit which corresponds to the obtained electrical capacity and is selected from the plurality of substrate holding/electrical capacity control units on a focus ring; and placing the mask substrate on the selected substrate holding/electrical capacity control unit.
